(19) United States
(12) Patent Application Publication
(10) Pub. No.: US 2026/0161087 A1
(43) Pub. Date: Jun. 11, 2026

(54) BISMUTH FILMS TARGETING EUV PHOTOLITHOGRAPHY APPLICATIONS

(71) Applicant: ENTEGRIS, INC., Billerica, MA (US)

(72) Inventors: David M. Ermert, Danbury, CT (US); Thomas M. Cameron, Newtown, CT (US); David Medeiros, West Stockbridge, MA (US)

(21) Appl. No.: 19/414,150

(22) Filed: Dec. 9, 2025

Related U.S. Application Data
(60) Provisional application No. 63/729,861, filed on Dec. 9, 2024.

(51) Int. Cl. G03F 7/16; G03F 7/00; G03F 7/004; G03F 7/20

(52) U.S. Cl. CPC G03F 7/167; G03F 7/0042; G03F 7/2004; G03F 7/70033

(57) ABSTRACT

Methods for making positive and negative tone photoresists are provided. The methods comprise obtaining a substrate comprises a bismuth and contacting the substrate with a precursor compound comprises a bismuth coordinated to at least one ligand to form a bismuth-containing film on a surface of the substrate. The at least one ligand comprises an oxygen or a sulfur. A portion of the bismuth-containing film is photo-exposed using extreme ultraviolet light to form a photo-exposed surface portion and a non-photo-exposed surface portion. To form a positive tone photoresist, the substrate is contacted with a solvent to remove the photo-exposed surface portion. To form a negative tone photoresist, the substrate is contacted with a solvent to remove the non-photo-exposed surface portion.

### CROSS-REFERENCE TO RELATED APPLICATIONS

This application claims the benefit under 35 USC 119 of U.S. Provisional Patent Application No. 63/729,861, filed Dec. 9, 2024, the disclosure of which is hereby incorporated herein by reference in its entirety.

### FIELD

The present disclosure relates to bismuth fims targeting EUV photolithography applications.

### BACKGROUND

Bismuth-containing films can be used in EUV photolithography applications to form both positive and negative tone photoresists.

### SUMMARY

Some embodiments relate to a method. In some embodiments, the method comprises obtaining a substrate comprising bismuth. In some embodiments, the method comprises obtaining a precursor compound comprising bismuth coordinated to at least one ligand. In some embodiments, the at least one ligand comprises an oxygen. In some embodiments, the method comprises heating the precursor compound to form a precursor vapor. In some embodiments, the method comprises contacting the substrate with the precursor vapor sufficient to form a bismuth-containing film on the substrate. In some embodiments, the method comprises photo-exposing a portion of a surface of the bismuth-containing film to obtain a photo-exposed surface portion and a non-photo-exposed surface portion. In some embodiments, the method comprises contacting the substrate with a solvent to remove the photo-exposed surface portion.

Some embodiments relate to a method. In some embodiments, the method comprises obtaining a substrate comprising a bismuth. In some embodiments, the method comprises obtaining a precursor compound comprising bismuth coordinated to at least one ligand. In some embodiments, the at least one ligand comprises a sulfur. In some embodiments, the method comprises heating the precursor compound to form a precursor vapor. In some embodiments, the method comprises contacting the substrate with the precursor vapor sufficient to form a bismuth-containing film on the substrate. In some embodiments, the method comprises photo-exposing a portion of a surface of the bismuth-containing film to obtain a photo-exposed surface portion and a non-photo-exposed surface portion. In some embodiments, the method comprises contacting the substrate with a solvent to remove the non-photo-exposed surface portion.

Some embodiments relate to a method. In some embodiments, the method comprises obtaining a substrate comprising a bismuth. In some embodiments, the method comprises contacting the substrate with a thiol-containing compound sufficient to form a layer of thiols on the substrate. In some embodiments, the method comprises photo-exposing a portion of a surface of the layer of thiols to obtain a photo-exposed surface portion and a non-photo-exposed surface portion. In some embodiments, the method comprises contacting the substrate with a solvent to remove the non-photo-exposed surface portion.

### BRIEF DESCRIPTION OF THE DRAWINGS

FIG. 1 is a flowchart of a method for making a positive tone photoresist, according to some embodiments.

FIG. 2 is a flowchart of a method for making a negative tone photoresist, according to some embodiments.

FIG. 3 is a flowchart of a method for making a negative tone photoresist, according to some embodiments.

FIG. 4 is an illustration of the method of making a positive tone photoresist of Example 1.

FIG. 5 is an illustration of the method of making a negative tone photoresist of Example 2.

FIG. 6 is an illustration of the method of making a negative tone photoresist of Example 3.

### DETAILED DESCRIPTION

Positive and negative tone photoresists can be formed by leveraging the difference in bond strengths of bismuth oxide versus bismuth sulfide as well as the difference in their solubility profiles.

As used herein, the term “alkyl” refers to a hydrocarbyl having from 1 to 30 carbon atoms. The alkyl may be attached via a single bond. An alkyl having n carbon atoms may be designated as a “Cₙ alkyl.” For example, a “C₃ alkyl” may include n-propyl and isopropyl. An alkyl having a range of carbon atoms, such as 1 to 30 carbon atoms, may be designated as a C₁-C₃₀ alkyl. In some embodiments, the alkyl is linear. In some embodiments, the alkyl is branched. In some embodiments, the alkyl is substituted. In some embodiments, the alkyl is unsubstituted. In some embodiments, the alkyl comprises or is selected from the group consisting of at least one of a C₁-C₃₀ alkyl, C₁-C₂₉ alkyl, C₁-C₂₈ alkyl, C₁-C₂₇ alkyl, C₁-C₂₇ alkyl, C₁-C₂₆ alkyl, C₁-C₂₅ alkyl, C₁-C₂₄ alkyl, C₁-C₂₃ alkyl, C₁-C₂₂ alkyl, C₁-C₂₁ alkyl, C₁-C₂₀ alkyl, C₁-C₁₉ alkyl, C₁-C₁₈ alkyl, C₁-C₁₇ alkyl, C₁-C₁₆ alkyl, C₁-C₁₅ alkyl, C₁-C₁₄ alkyl, C₁-C₁₃ alkyl, C₁-C₁₂ alkyl, C₁-C₁₁ alkyl, C₁-C₁₀ alkyl, a C₁-C₉ alkyl, a C₁-C₈ alkyl, a C₁-C₇ alkyl, a C₁-C₆ alkyl, a C₁-C₅ alkyl, a C₁-C₄ alkyl, a C₁-C₃ alkyl, a C₁-C₂ alkyl, a C₂-C₃₀ alkyl, a C₃-C₃₀ alkyl, a C₄-C₃₀ alkyl, a C₅-C₃₀ alkyl, a C₆-C₃₀ alkyl, a C₇-C₃₀ alkyl, a C₈-C₃₀ alkyl, a C₉-C₃₀ alkyl, a C₁₀-C₃₀ alkyl, a C₁₁-C₃₀ alkyl, a C₁₂-C₃₀ alkyl, a C₁₃-C₃₀ alkyl, a C₁₄-C₃₀ alkyl, a C₁₅-C₃₀ alkyl, a C₁₆-C₃₀ alkyl, a C₁₇-C₃₀ alkyl, a C₁₈-C₃₀ alkyl, a C₁₉-C₃₀ alkyl, a C₂₀-C₃₀ alkyl, a C₂₁-C₃₀ alkyl, a C₂₂-C₃₀ alkyl, a C₂₃-C₃₀ alkyl, a C₂₄-C₃₀ alkyl, a C₂₅-C₃₀ alkyl, a C₂₆-C₃₀ alkyl, a C₂₇-C₃₀ alkyl, a C₂₈-C₃₀ alkyl, a C₂₉-C₃₀ alkyl, a C₂-C₁₀ alkyl, a C₃-C₁₀ alkyl, a C₄-C₁₀ alkyl, a C₅-C₁₀ alkyl, a C₆-C₁₀ alkyl, a C₇-C₁₀ alkyl, a C₈-C₁₀ alkyl, a C₂-C₉ alkyl, a C₂-C₈ alkyl, a C₂-C₇ alkyl, a C₂-C₆ alkyl, a C₂-C₅ alkyl, a C₃-C₅ alkyl, or any combination thereof. In some embodiments, the alkyl comprises or is selected from the group consisting of at least one of methyl, ethyl, n-propyl, 1-methylethyl (iso-propyl), n-butyl, iso-butyl, sec-butyl, n-pentyl, 1,1-dimethylethyl (t-butyl), n-pentyl, iso-pentyl, n-hexyl, isohexyl, 3-methylhexyl, 2-methylhexyl, heptyl, octyl, nonyl, decyl, dodecyl, octadecyl, or any combination thereof. In some embodiments, the term “alkyl” refers generally to alkyls, alkenyls, alkynyls, and/or cycloalkyls.

As used herein, the term “alkenyl” refers to a hydrocarbyl having from 1 to 30 carbon atoms and at least one carbon-carbon double bond. In some embodiments, the alkenyl comprises or is selected from the group consisting of at least one of a C₁-C₃₀ alkenyl, C₁-C₂₉ alkenyl, C₁-C₂₈ alkenyl, C₁-C₂₇ alkenyl, C₁-C₂₇ alkenyl, C₁-C₂₆ alkenyl, C₁-C₂₅ alkenyl, C₁-C₂₄ alkenyl, C₁-C₂₃ alkenyl, C₁-C₂₂ alkenyl, C₁-C₂₁ alkenyl, C₁-C₂₀ alkenyl, C₁-C₁₉ alkenyl, C₁-C₁₈ alkenyl, C₁-C₁₇ alkenyl, C₁-C₁₆ alkenyl, C₁-C₁₅ alkenyl, C₁-C₁₄ alkenyl, C₁-C₁₃ alkenyl, C₁-C₁₂ alkenyl, C₁-C₁₁ alkenyl, C₁-C₁₀ alkenyl, a C₁-C₉ alkenyl, a C₁-C₈ alkenyl, a C₁-C₇ alkenyl, a C₁-C₆ alkenyl, a C₁-C₅ alkenyl, a C₁-C₄ alkenyl, a C₁-C₃ alkenyl, a C₁-C₂ alkenyl, a C₂-C₃₀ alkenyl, a C₃-C₃₀ alkenyl, a C₄-C₃₀ alkenyl, a C₅-C₃₀ alkenyl, a C₆-C₃₀ alkenyl, a C₇-C₃₀ alkenyl, a C₈-C₃₀ alkenyl, a C₉-C₃₀ alkenyl, a C₁₀-C₃₀ alkenyl, a C₁₁-C₃₀ alkenyl, a C₁₂-C₃₀ alkenyl, a C₁₃-C₃₀ alkenyl, a C₁₄-C₃₀ alkenyl, a C₁₅-C₃₀ alkenyl, a C₁₆-C₃₀ alkenyl, a C₁₇-C₃₀ alkenyl, a C₁₈-C₃₀ alkenyl, a C₁₉-C₃₀ alkenyl, a C₂₀-C₃₀ alkenyl, a C₂₁-C₃₀ alkenyl, a C₂₂-C₃₀ alkenyl, a C₂₃-C₃₀ alkenyl, a C₂₄-C₃₀ alkenyl, a C₂₅-C₃₀ alkenyl, a C₂₆-C₃₀ alkenyl, a C₂₇-C₃₀ alkenyl, a C₂₈-C₃₀ alkenyl, a C₂₉-C₃₀ alkenyl, a C₂-C₁₀ alkenyl, a C₃-C₁₀ alkenyl, a C₄-C₁₀ alkenyl, a C₅-C₁₀ alkenyl, a C₆-C₁₀ alkenyl, a C₇-C₁₀ alkenyl, a C₈-C₁₀ alkenyl, a C₂-C₉ alkenyl, a C₂-C₈ alkenyl, a C₂-C₇ alkenyl, a C₂-C₆ alkenyl, a C₂-C₅ alkenyl, a C₃-C₅ alkenyl, or any combination thereof. Examples of alkenyl groups include, without limitation, at least one of vinyl, allyl, 1-methylvinyl, 1-propenyl, 1-butenyl, 2-butenyl, 3-butenyl, 1,3-butadienyl, 2-methyl-1-propenyl, 2-methyl-2-propenyl, 1-pentenyl, 2-pentenyl, 3-pentenyl, 4-pentenyl, 1,3-pentadienyl, 2,4-pentadienyl, 1,4-pentadienyl, 3-methyl-2-butenyl, 1-hexenyl, 2-hexenyl, 3-hexenyl, 1,3-hexadienyl, 1,4-hexadienyl, 2-methylpentenyl, 1-heptenyl, 3-heptenyl, 1-octenyl, 1,3-octadienyl, 1-nonenyl, 2-nonenyl, 3-nonenyl, 1-decenyl, 3-decenyl, 1-undecenyl, oleyl, linoleyl, linolenyl, or any combination thereof.

As used herein, the term “alkynyl” refers to a hydrocarbyl having from 1 to 30 carbon atoms and at least one carbon-carbon triple bond. In some embodiments, the alkynyl comprises or is selected from the group consisting of at least one of a C₁-C₃₀ alkynyl, C₁-C₂₉ alkynyl, C₁-C₂₈ alkynyl, C₁-C₂₇ alkynyl, C₁-C₂₇ alkynyl, C₁-C₂₆ alkynyl, C₁-C₂₅ alkynyl, C₁-C₂₄ alkynyl, C₁-C₂₃ alkynyl, C₁-C₂₂ alkynyl, C₁-C₂₁ alkynyl, C₁-C₂₀ alkynyl, C₁-C₁₉ alkynyl, C₁-C₁₈ alkynyl, C₁-C₁₇ alkynyl, C₁-C₁₆ alkynyl, C₁-C₁₅ alkynyl, C₁-C₁₄ alkynyl, C₁-C₁₃ alkynyl, C₁-C₁₂ alkynyl, C₁-C₁₁ alkynyl, C₁-C₁₀ alkynyl, a C₁-C₉ alkynyl, a C₁-C₈ alkynyl, a C₁-C₇ alkynyl, a C₁-C₆ alkynyl, a C₁-C₅ alkynyl, a C₁-C₄ alkynyl, a C₁-C₃ alkynyl, a C₁-C₂ alkynyl, a C₂-C₃₀ alkynyl, a C₃-C₃₀ alkynyl, a C₄-C₃₀ alkynyl, a C₅-C₃₀ alkynyl, a C₆-C₃₀ alkynyl, a C₇-C₃₀ alkynyl, a C₈-C₃₀ alkynyl, a C₉-C₃₀ alkynyl, a C₁₀-C₃₀ alkynyl, a C₁₁-C₃₀ alkynyl, a C₁₂-C₃₀ alkynyl, a C₁₃-C₃₀ alkynyl, a C₁₄-C₃₀ alkynyl, a C₁₅-C₃₀ alkynyl, a C₁₆-C₃₀ alkynyl, a C₁₇-C₃₀ alkynyl, a C₁₈-C₃₀ alkynyl, a C₁₉-C₃₀ alkynyl, a C₂₀-C₃₀ alkynyl, a C₂₁-C₃₀ alkynyl, a C₂₂-C₃₀ alkynyl, a C₂₃-C₃₀ alkynyl, a C₂₄-C₃₀ alkynyl, a C₂₅-C₃₀ alkynyl, a C₂₆-C₃₀ alkynyl, a C₂₇-C₃₀ alkynyl, a C₂₈-C₃₀ alkynyl, a C₂₉-C₃₀ alkynyl, a C₂-C₁₀ alkynyl, a C₃-C₁₀ alkynyl, a C₄-C₁₀ alkynyl, a C₅-C₁₀ alkynyl, a C₆-C₁₀ alkynyl, a C₇-C₁₀ alkynyl, a C₈-C₁₀ alkynyl, a C₂-C₉ alkynyl, a C₂-C₈ alkynyl, a C₂-C₇ alkynyl, a C₂-C₆ alkynyl, a C₂-C₅ alkynyl, a C₃-C₅ alkynyl, or any combination thereof. Examples of alkynyl groups include, without limitation, at least one of ethynyl, propynyl, n-butynyl, n-pentynyl, 3-methyl-1-butynyl, n-hexynyl, methyl-pentynyl, or any combination thereof.

As used herein, the term “cycloalkyl” refers to a non-aromatic carbocyclic ring having from 3 to 8 carbon atoms in the ring. The term includes a monocyclic non-aromatic carbocyclic ring and a polycyclic non-aromatic carbocyclic ring. The term “monocyclic,” when used as a modifier, refers to a cycloalkyl having a single cyclic ring structure. The term “polycyclic,” when used as a modifier, refers to a cycloalkyl having more than one cyclic ring structure, which may be fused, bridged, spiro, or otherwise bonded ring structures. For example, two or more cycloalkyls may be fused, bridged, or fused and bridged to obtain the polycyclic non-aromatic carbocyclic ring. In some embodiments, the cycloalkyl may comprise, consist of, or consist essentially of, or may be selected from the group consisting of, at least one of cyclopropyl, cyclobutyl, cyclopentyl, cyclohexyl, cycloheptyl, cyclooctyl, or any combination thereof.

As used herein, the term “aryl” refers to a monocyclic or polycyclic aromatic hydrocarbon. The number of carbon atoms of the aryl may be in a range of 5 carbon atoms to 100 carbon atoms. In some embodiments, the aryl has 5 to 20 carbon atoms. For example, in some embodiments, the aryl has 6 to 8 carbon atoms, 6 to 10 carbon atoms, 6 to 12 carbon atoms, 6 to 15 carbon atoms, or 6 to 20 carbon atoms. The term “monocyclic,” when used as a modifier, refers to an aryl having a single aromatic ring structure. The term “polycyclic,” when used as a modifier, refers to an aryl having more than one aromatic ring structure, which may be fused, bridged, spiro, or otherwise bonded ring structures. In some embodiments, the aryl is —C₆H₅.

Non-limiting examples of aryls include, without limitation, at least one of benzene, toluene, xylene (e.g., o-xylene, m-xylene, p-xylene), t-butyltoluene (e.g., o-t-butyltoluene, m-t-butyltoluene, p-t-butyltoluene), ethylmethylbenzene (e.g., 1-ethyl-4-methylbenzene, 1-ethyl-3-methylbenzene), 1-isopropyl-4-methylbenzene, 1-t-butyl-4-methylbenzene, mesitylene, pseudocumene, durene, methylbenzene, dimethylbenzene, trimethylbenzene, ethylbenzene, diethylbenzene (e.g., 1,4-diethylbenzene), triethylbenzene, propylbenzene, butylbenzene, iso-butylbenzene, sec-butylbenzene, t-butylbenzene, hexylbenzene, styrene, naphthalene, anthracene, phenanthrene, biphenyl, terphenyl, methylnaphthalene, biphenylene, dimethylnaphthalene, methylanthracene, 4,4′-dimethylbiphenyl, bibenzyl, diphenylmethane, any isomer thereof, or any combination thereof, and the like.

As used herein, the term “amino” and/or “amine” refers to a functional group of formula —N(R^{a}R^{b}), wherein R^{a} and R^{b} are independently a hydrogen, an alkyl (as defined herein), an aminoalkyl (as defined herein), or a silyl (as defined herein), or R^{a} and R^{b} are bonded to each other to form a C₃-C₂₀ N-heterocycle. In some embodiments, the amino may comprise an alkylamino or a dialkylamino. In some embodiments, the amino may comprise at least one of methylamino, dimethylamino, ethylamino, diethylamino, isopropylamino, di-isopropylamino, butylamino, sec-butylamino, tert-butylamino, di-sec-butylamino, isobutylamino, di-isobutylamino, di-tert-pentylamino, ethylmethylamino, isopropyl-n-propylamino, or any combination thereof. Examples of the alkylamines may include, without limitation, one or more of the following: primary alkylamines, such as, for example and without limitation, methylamine, ethylamine, n-propylamine, isopropylamine, n-butylamine, sec-butylamine, isobutylamine, t-butylamine, pentylamine, 2-aminopentane, 3-aminopentane, 1-amino-2-methylbutane, 2-amino-2-methylbutane, 3-amino-2-methylbutane, 4-amino-2-methylbutane, hexylamine, 5-amino-2-methylpentane, heptylamine, octylamine, nonylamine, decylamine, undecylamine, dodecylamine, tridecylamine, tetradecylamine, pentadecylamine, hexadecylamine, heptadecylamine, and octadecylamine; secondary alkylamines, such as, for example and without limitation, dimethylamine, diethylamine, dipropylamine, diisopropylamine, dibutylamine, diisobutylamine, di-sec-butylamine, di-t-butylamine, dipentylamine, dihexylamine, diheptylamine, dioctylamine, dinonylamine, didecylamine, methylethylamine, methylpropylamine, methylisopropylamine, methylbutylamine, methylisobutylamine, methyl-sec-butylamine, methyl-t-butylamine, methylamylamine, methylisoamylamine, ethylpropylamine, ethylisopropylamine, ethylbutylamine, ethylisobutylamine, ethyl-sec-butylamine, ethylamine, ethylisoamylamine, propylbutylamine, and propylisobutylamine; and tertiary alkylamines, such as, for example and without limitation, trimethylamine, triethylamine, tripropylamine, tributylamine, tripentylamine, dimethylethylamine, methyldiethylamine, and methyldipropylamine. Examples of polyamines may include, without limitation, one or more of the following: ethylenediamine, propylenediamine, trimethylenediamine, tetramethylenediamine, 1,3-diaminobutane, 2,3-diaminobutane, pentamethylenediamine, 2,4-diaminopentane, hexamethylenediamine, heptamethylenediamine, octamethylenediamine, nonamethylenediamine, N-methylethylenediamine, N,N-dimethylethylenediamine, trimethylethylenediamine, N-ethylethylenediamine, N,N-diethylethylenediamine, triethylethylenediamine, 1,2,3-triaminopropane, hydrazine, tris(2-aminoethyl)amine, tetra(aminomethyl)methane, diethylenetriamine, triethylenetetramine, tetraethylpentamine, heptaethyleneoctamine, nonaethylenedecamine, and diazabicyloundecene. Unless otherwise provided herein, the terms “amine” and “amino” may be used interchangeably throughout this disclosure.

As used herein, the term “alkoxy” or “alkoxide” refers to a functional group of formula —OR^{c}, wherein R^{c} is an alkyl (as defined herein), a silylalkyl, a cycloalkyl, or an aryl. In some embodiments, the alkoxy may comprise, consist of, or consist essentially of, or may selected from the group consisting of, at least one of methoxy, ethoxy, methoxy, ethoxy, n-propoxy, 1-methylethoxy (isopropoxy), n-butoxy, iso-butoxy, sec-butoxy, tert-butoxy, or any combination thereof.

As used herein, the term “silyl” refers to a functional group of formula —Si(R^{e}R^{f}R^{g}), where each of R^{e}, R^{f}, and R^{g} is independently a hydrogen or an alkyl, as defined herein. In some embodiments, the silyl is a functional group of formula —SiH₃. In some embodiments, the silyl is a functional group of formula —SiR^{e}H₂, where R^{e} is not hydrogen. In some embodiments, the silyl is a functional group of formula —SiR^{e}R^{f}H, where R^{e} and R^{f} are not hydrogen. In some embodiments, the silyl is a functional group of the formula —Si(R^{e}R^{f}R^{g}), where R^{e}, R^{f}, and R^{g} are not hydrogen. In some embodiments, the silyl is a functional group of formula —Si(CH₃)₃.

As used herein, the term “oxysilyl” refers to a functional group of formula —OSi(R^{e}R^{f}R^{g}), where each of R^{e}, R^{f}, and R^{g} is independently a hydrogen or an alkyl, as defined herein. In some embodiments, the silyl is a functional group of formula —SiH₃. In some embodiments, the silyl is a functional group of formula —SiR^{e}H₂, where R^{e} is not hydrogen. In some embodiments, the silyl is a functional group of formula —SiR^{e}R^{f}H, where R^{e} and R^{f} are not hydrogen. In some embodiments, the silyl is a functional group of the formula —Si(R^{e}R^{f}R^{g}), where R^{e}, R^{f}, and R^{g} are not hydrogen. In some embodiments, the silyl is a functional group of formula —Si(CH₃)₃.

As used herein, the term “alkoxyalkyl” refers to an alkyl as defined herein, wherein at least one of the hydrogen atoms of the alkyl is replaced with an alkoxy as defined herein. In some embodiments, the term “alkoxyalkyl” refers to a functional group of formula -(alkyl)OR^{a}, wherein the alkyl is defined above and wherein the R^{a} is defined above. In some embodiments, the alkoxyalkyl is a functional group of formula —(CH₂)ₙOR^{a}, where n is 1 to 10 and R^{a} is defined above. In some embodiments, the alkoxyalkyl is a functional group of the formula —CH₂CH₂OCH₃.

As used herein, the term “aralkyl” refers to an alkyl as defined herein, wherein at least one of the hydrogen atoms of the alkyl is replaced with an aryl as defined herein. In some embodiments, the term “aralkyl” refers to a functional group of formula-(alkyl) (aryl), wherein the alkyl is defined herein and the aryl is defined herein. In some embodiments, the aralkyl is —CH₂(C₆H₅).

As used herein, the term “aminoalkyl” refers to an alkyl as defined herein, wherein at least one of the hydrogen atoms of the alkyl is replaced with an amino as defined herein. In some embodiments, the term “aminoalkyl” refers to a functional group of formula -(alkyl)N(R^{b}R^{c}R^{d}), wherein the alkyl is defined above and wherein R^{b}, R^{c}, and R^{d} are defined above. In some embodiments, the aminoalkyl is —CH₂N(CH₃)₂. In some embodiments, the aminoalkyl is —(CH₂)₃N(CH₃)₂. In some embodiments, the aminoalkyl is aminomethyl (—CH₂NH₂). In some embodiments, the aminoalkyl is N,N-dimethylaminoethyl (—CH₂CH₂N(CH₃)₂). In some embodiments, the aminoalkyl is 3-(N-cyclopropylamino) propyl (—CH₂CH₂CH₂NH—Pr).

As used herein, the term “silylalkyl” refers to an alkyl as defined herein, wherein at least one of the hydrogen atoms of the alkyl is replaced with a silyl as defined herein. In some embodiments, the term “silylalkyl” refers to a functional group of formula -(alkyl) Si(R^{e}R^{f}R^{g}), wherein the alkyl is defined above and wherein R^{e}, R^{f}, and R^{g} are defined above. In some embodiments, the silylalky is a functional group of formula —(CH₂)ₘSi(R^{e}R^{f}R^{g}), where m is 1 to 10 and where R^{e}, R^{f}, and R^{g} are defined above. In some embodiments, the silylalkyl is a functional group of formula —CH₂Si(CH₃)₃.

As used herein, the term “haloalkyl” refers to an alkyl as defined here, wherein at least one of the hydrogen atoms of the alkyl is replaced with a halide as defined herein. In some embodiments, the haloalkyl comprises a fluoroalkyl. In some embodiments, the fluoroalkyl comprises at least one of —CH₂CF₃, —CH(CF₃)₂, —CH₂F, —CH₂CH₂F, —CF₃, —CF₂CF₃, or any combination thereof.

As used herein, the term “thiol” refers to a functional group of formula —SR^{a}, wherein R^{a} is a hydrogen, an alkyl (as defined herein), an amino (as described herein), an alkoxy (as described herein), an alkylamino (as described herein), an alkoxyalkyl (as described herein), a carbonyl (as described herein), or any combination thereof. In some embodiments, the term “thiol” refers to a functional group of formula —SH. In some embodiments, the term “thiol” refers to a functional group of formula —SCH₃.

As used herein, the term “alkylthiol” refers to a compound of formula —R^{a}SR^{b}, wherein R^{a} is an alkyl, as described herein, and R^{b} is a hydrogen, an alkyl (as defined herein), an amino (as described herein), an alkoxy (as described herein), an alkylamino (as described herein), an alkoxyalkyl (as described herein), a carbonyl (as described herein), or any combination thereof. In some embodiments, the term “alkylthiol” refers to a compound of formula —R^{a}SH, wherein R^{a} is an alkyl, as described herein.

As used herein, the term “thiourea” refers to a compound of formula-R^{a}C(═S)R^{b}, wherein R^{a} and R^{b} are independently an amino, as described herein.

As used herein, the term “thioester” refers to a functional group of formula —SC(═O)R^{a}, wherein R^{a} is a hydrogen, an alkyl (as defined herein), an amino (as described herein), an alkoxy (as described herein), an alkylamino (as described herein), an alkoxyalkyl (as described herein), or any combination thereof. In some embodiments, the term “thioester” refers to a functional group of formula —SC(═O)H. In some embodiments, the term “thioester” refers to a functional group of formula —SC(═O)CH₃.

As used herein, the term “thiocarbonylthio” refers to a functional group of formula —SC(═S)R^{a}, wherein R^{a} is a hydrogen or an alkyl, as defined herein. In some embodiments, the term “thiocarbonylthio” refers to a functional group of formula —SC(═S)H. In some embodiments, the term “thiocarbonylthio” is a functional group of formula —SC(═S)CH₃.

As used herein, the term “amidine” refers to a functional group of formula —C(═NR^{a})N(R^{b}R^{c}), wherein R^{a}, R^{b}, and R^{c} are each independently a hydrogen or an alkyl, as defined here. In some embodiments, the term “amidine” refers to a functional group of formula —C(═NH)N(R^{b}R^{c}), where R^{b} and R^{c} are not hydrogen. In some embodiments, the term “amidine” refers to a functional group of formula —C(═NR^{a})N(HR^{c}), where R^{a} and R^{c} are not hydrogen. In some embodiments, the term “amidine” refers to a functional group of formula —C(═NH)N(HR^{c}), where R^{c} is not hydrogen. In some embodiments, the term “amidine” refers to a functional group of formula —C(═NR^{a})N(R^{b}R^{c}), wherein R^{a}, R^{b}, and R^{c} are not hydrogen.

As used herein, the term “guanidine” refers to a functional group of formula —C(═NR^{a})N(R^{b}R^{c})N(R^{d}R^{e}), wherein R^{a}, R^{b}, R^{c}, R^{d}, and R^{e} are each independently a hydrogen or an alkyl, as defined here. In some embodiments, the term “guanidine” refers to a functional group of formula —C(═NH)N(R^{b}R^{c})N(R^{d}R^{e}), wherein R^{b}, R^{c}, R^{d}, and R^{e} are not hydrogen. In some embodiments, the term “guanidine” refers to a functional group of formula —C(═NR^{a})N(HR^{c})N(R^{d}R^{e}), wherein R^{a}, R^{c}, R^{d}, and R^{e} are not hydrogen. In some embodiments, the term “guanidine” refers to a functional group of formula —C(═NR^{a})N(H₂)N(R^{d}R^{e}), wherein R^{a}, R^{d}, and R^{e} are not hydrogen. In some embodiments, the term “guanidine” refers to a functional group of formula —C(═NH)N(HR^{c})N(R^{d}R^{e}), wherein R^{c}, R^{d}, and R^{e} are not hydrogen. In some embodiments, the term “guanidine” refers to a functional group of formula —C(═NR^{a})N(H₂)N(HR^{e}), wherein R^{a} and R^{e} are not hydrogen. In some embodiments, the term “guanidine” refers to a functional group of formula —C(═NH)N(H₂)N(HR^{e}), wherein R^{e} is not hydrogen.

As used herein, the term “carbonyl” refers to a functional group of formula —C(═O)R^{a}, wherein R^{a} is a hydrogen or an alkyl, as defined herein. In some embodiments, the term “carbonyl” refers to a functional group of formula —C(═O)H. In some embodiments, the term “carbonyl” is a functional group of formula —C(═O)CH₃.

As used herein, the term “halide” refers to a —Cl, —Br, —I, or —F.

As used herein, the term “ethynyl” refers to —C≡CH.

As used herein, the term “phenyl” refers to —C₆H₅.

As used herein, the term “allyl” refers to —CH₂CH═CH₂.

As used herein, the term “vinyl” refers to —CH═CH₂.

As used herein, the term “acetoxy” refers to —OC(═O)CH₃.

Some embodiments relate to precursors and related methods. At least some of these embodiments relate to precursors useful in the fabrication of microelectronic devices, including semiconductor devices, and the like. For example, the precursors can be used to form films by one or more deposition processes. Examples of deposition processes include, without limitation, at least one of a chemical vapor deposition (CVD) process, a digital or pulsed chemical vapor deposition process, a plasma-enhanced cyclical chemical vapor deposition (PECCVD) process, a flowable chemical vapor deposition (FCVD) process, an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

Some embodiments relate to a composition comprising a bismuth-containing compound. In some embodiments, the composition comprises a compound of the formula:

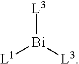

In some embodiments, each of L¹, L², or L³ independently comprises at least one of a hydrogen, an alkyl, an alkenyl, an alkynyl, an aryl, a cycloalkyl, an alkoxy, an oxysilyl, an alkoxyalkyl, an aralkyl, a thiol, a thiocarbonylthio, a thioester, an amino, an amidine, a guanidine, a carbonyl, a halogen, or any combination thereof. In some embodiments, at least two of L¹, L², or L³ are bonded to form a cyclic ring. In some embodiments, L¹, L², or L³ are coordinated to the bismuth atom.

In some embodiments, at least one of L¹, L², or L³ comprises an amine.

In some embodiments, at least two of L¹, L², or L³ comprises an amine.

In some embodiments, at least two of L¹, L², or L³ comprises an alkoxy.

In some embodiments, at least two of L¹, L², or L³ comprises a thiol.

In some embodiments, each of L¹, L², or L³ comprises an amine.

In some embodiments, each of L¹, L², or L³ comprises an alkoxy.

In some embodiments, each of L¹, L², or L³ comprises a thiol.

In some embodiments, each of L¹, L², or L³ comprises an alkyl.

In some embodiments, each of L¹, L², or L³ comprises a thiocarbonylthio.

In some embodiments, two of L¹, L², or L³ are bonded to form a cyclic ring. In some embodiments, the cyclic ring is an aromatic ring. In some embodiments, the cyclic ring comprises at least one heteroatom. In some embodiments, the heteroatom comprises a nitrogen, an oxygen, a sulfur, or any combination thereof.

Some embodiments relate to methods for making a positive tone photoresist.

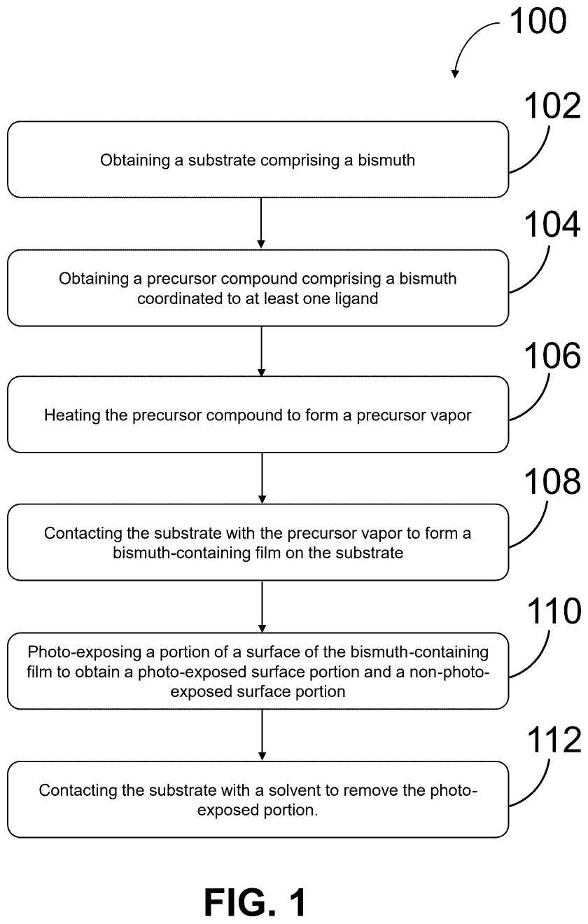

FIG. 1 is a flowchart of a method 100 for making a positive tone photoresist, according to some embodiments. As shown in FIG. 1, the method 100 for making a positive tone photoresist may comprise one or more of the following steps: obtaining a substrate comprising a bismuth 102, obtaining a precursor compound comprising a bismuth coordinated to at least one ligand 104, heating the precursor compound to form a precursor vapor 106, contacting the substrate with the precursor vapor sufficient to form a bismuth-containing film on the substrate 108, photo-exposing a portion of a surface of the bismuth-containing film to obtain a photo-exposed surface portion and a non-photo-exposed surface portion 110, and contacting the substrate with a solvent to remove the photo-exposed surface portion 112.

At step 102, in some embodiments, the method comprises obtaining a substrate comprising a bismuth. In some embodiments, the substrate consists of bismuth. In some embodiments, the substrate comprises a bismuth, a bismuth oxide, a bismuth sulfide, or any combination thereof. In some embodiments, the substrate comprises a bismuth with a bismuth oxide film on a surface of the substrate. In some embodiments, the substrate comprises bismuth with a bismuth sulfide film on a surface of the substrate.

In some embodiments, the bismuth sulfide film on the surface of the substrate is obtained by contacting the substrate with a thiol-containing compound sufficient to form a layer of thiols on the substrate and photo-exposing the layer of thiols to form the bismuth sulfide film. In some embodiments, the thiol-containing compound comprises an alkylthiol, a thiourea, or a combination thereof.

In some embodiments, the obtaining comprises obtaining a vessel comprising the substrate. In some embodiments, the obtaining comprises obtaining a container comprising the substrate. In some embodiments, the substrate may be obtained in a container or vessel in which the substrate will be contacted with the precursor compound.

At step 104, in some embodiments, the method comprises obtaining a precursor compound comprising a bismuth coordinated to at least one ligand. In some embodiments, the at least one ligand comprises an oxygen. In some embodiments, the precursor compound is any of the precursor compounds discussed herein. In some embodiments, the precursor compound is any of the precursor compounds discussed herein that contain an oxygen.

In some embodiments, the obtaining comprises obtaining a vessel comprising the precursor compound. In some embodiments, the obtaining comprises obtaining a container comprising the precursor compound. In some embodiments, the precursor compound may be obtained in a container or other vessel in which the precursor compound is to be heated.

At step 106, in some embodiments, the method comprises heating the precursor compound to obtain a precursor vapor. The heating may comprise heating the precursor compound sufficient to obtain the precursor vapor. In some embodiments, the heating comprises heating a container comprising the precursor compound. In some embodiments, the heating comprises heating the precursor compound in a deposition chamber in which the vapor deposition process is performed. In some embodiments, the heating comprises heating a conduit for delivering the precursor compound, the precursor vapor, or any combination thereof to, for example, a deposition chamber. In some embodiments, the heating comprises operating a vapor delivery system comprising the precursor compound. In some embodiments, the heating comprises heating to a temperature sufficient to vaporize the precursor compound to obtain the precursor vapor. In some embodiments, the heating comprises heating to a temperature below a decomposition temperature of at least one of the precursor compound, the precursor vapor, or any combination thereof. In some embodiments, the precursor compound may be present in a gas phase or other vaporizable phase, in which case the step 106 is optional and not required. For example, in some embodiments, the precursor compound comprises the precursor vapor.

At step 108, in some embodiments, the method comprises contacting the substrate with the precursor vapor to form a bismuth-containing film on the substrate. In some embodiments, the precursor vapor may be contacted with a bismuth sulfide film on a surface of the substrate. In some embodiments, the contacting comprises contacting the substrate under vapor deposition conditions. The contacting may be performed in any system, apparatus, device, assembly, chamber thereof, or component thereof suitable for vapor deposition processes, including, for example and without limitation, a deposition chamber, among others.

The vapor deposition conditions may comprise conditions for vapor deposition processes. Examples of vapor deposition conditions include, without limitation, vapor deposition conditions for vapor deposition processes including at least one of a chemical vapor deposition (CVD) process, a digital or pulsed chemical vapor deposition process, a plasma-enhanced cyclical chemical vapor deposition (PECCVD) process, a flowable chemical vapor deposition (FCVD) process, an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

The vapor deposition conditions may comprise a deposition temperature. The deposition temperature may be a temperature less than the thermal decomposition temperature of the precursor vapor. The deposition temperature may be sufficiently high to reduce or avoid condensation of the precursor vapor. In some embodiments, the substrate may be heated to the deposition temperature. In some embodiments, the chamber or other vessel in which the substrate is contacted with the precursor vapor. In some embodiments, the precursor vapor may be heated to the deposition temperature.

The deposition temperature may be a temperature of 200° C. to 2500° C., or any range or subrange between 200° C. and 2500° C. In some embodiments, the deposition temperature may be a temperature of 500° C. to 700° C. For example, in some embodiments, the deposition temperature may be a temperature of 500° C. to 680° C., 500° C. to 660° C., 500° C. to 640° C., 500° C. to 620° C., 500° C. to 600° C., 500° C. to 580° C., 500° C. to 560° C., 500° C. to 540° C., 500° C. to 520° C., 520° C. to 700° C., 540° C. to 700° C., 560° C. to 700° C., 580° C. to 700° C., 600° C. to 700° C., 620° C. to 700° C., 640° C. to 700° C., 660° C. to 700° C., or 680° C. to 700° C. In other embodiments, the deposition temperature may be a temperature of greater than 200° C. to 2500° C., such as, for example and without limitation, a temperature of 400° C. to 2000, 500° C. to 2000° C., 550° C. to 2400° C., 600° C. to 2400° C., 625° C. to 2400° C., 650° C. to 2400° C., 675° C. to 2400° C., 700° C. to 2400° C., 725° C. to 2400° C., 750° C. to 2400° C., 775° C. to 2400° C., 800° C. to 2400° C., 825° C. to 2400° C., 850° C. to 2400° C., 875° C. to 2400° C., 900° C. to 2400° C., 925° C. to 2400° C., 950° C. to 2400° C., 975° C. to 2400° C., 1000° C. to 2400° C., 1025° C. to 2400° C., 1050° C. to 2400° C., 1075° C. to 2400° C., 1100° C. to 2400° C., 1200° C. to 2400° C., 1300° C. to 2400° C., 1400° C. to 2400° C., 1500° C. to 2400° C., 1600° C. to 2400° C., 1700° C. to 2400° C., 1800° C. to 2400° C., 1900° C. to 2400° C., 2000° C. to 2400° C., 2100° C. to 2400° C., 2200° C. to 2400° C., 2300° C. to 2400° C., 500° C. to 2000° C., 500° C. to 1900° C., 500° C. to 1800° C., 500° C. to 1700° C., 500° C. to 1600° C., 500° C. to 1500° C., 500° C. to 1400° C., 500° C. to 1300° C., 500° C. to 1200° C., 500° C. to 1100° C., 500° C. to 1000° C., 500° C. to 1000° C., 500° C. to 900° C., or 500° C. to 800° C.

The vapor deposition conditions may comprise a deposition pressure. In some embodiments, the deposition pressure may comprise a vapor pressure of the precursor vapor. In some embodiments, the deposition pressure may comprise a chamber pressure.

The deposition pressure may be a pressure of 0.001 Torr to 100 Torr, or any range or subrange between 0.001 Torr and 100 Torr. For example, in some embodiments, the deposition pressure may be a pressure of 1 Torr to 30 Torr, 1 Torr to 25 Torr, 1 Torr to 20 Torr, 1 Torr to 15 Torr, 1 Torr to 10 Torr, 5 Torr to 50 Torr, 5 Torr to 40 Torr, 5 Torr to 30 Torr, 5 Torr to 20 Torr, or 5 Torr to 15 Torr. In other embodiments, the deposition pressure may be a pressure of 1 Torr to 100 Torr, 5 Torr to 100 Torr, 10 Torr to 100 Torr, 15 Torr to 100 Torr, 20 Torr to 100 Torr, 25 Torr to 100 Torr, 30 Torr to 100 Torr, 35 Torr to 100 Torr, 40 Torr to 100 Torr, 45 Torr to 100 Torr, 50 Torr to 100 Torr, 55 Torr to 100 Torr, 60 Torr to 100 Torr, 65 Torr to 100 Torr, 70 Torr to 100 Torr, 75 Torr to 100 Torr, 80 Torr to 100 Torr, 85 Torr to 100 Torr, 90 Torr to 100 Torr, 95 Torr to 100 Torr, 1 Torr to 95 Torr, 1 Torr to 90 Torr, 1 Torr to 85 Torr, 1 Torr to 80 Torr, 1 Torr to 75 Torr, or 1 Torr to 70 Torr. In other further embodiments, the deposition pressure may be a pressure of 1 mTorr to 100 mTorr, 1 mTorr to 90 mTorr, 1 mTorr to 80 mTorr, 1 mTorr to 70 mTorr, 1 mTorr to 60 mTorr, 1 mTorr to 50 mTorr, 1 mTorr to 40 mTorr, 1 mTorr to 30 mTorr, 1 mTorr to 20 mTorr, 1 mTorr to 10 mTorr, 100 mTorr to 300 mTorr, 150 mTorr to 300 mTorr, 200 mTorr to 300 mTorr, or 150 mTorr to 250 mTorr, or 150 mTorr to 225 mTorr.

At step 110, in some embodiments, the method comprises photo-exposing a portion of a surface of the bismuth-containing film to obtain a photo-exposed surface portion and a non-photo-exposed surface portion. In some embodiments, the photo-exposing is conducted using extreme ultraviolet light. In some embodiments, the photo-exposed surface portion comprises a bismuth oxide.

At step 112, in some embodiments, the method comprises contacting the substrate with a solvent to remove the photo-exposed surface portion. In some embodiments, the contacting involves washing the substrate with the solvent. In some embodiments, the contacting involves wiping the substrate with the solvent. In some embodiments, the contacting involves spraying the substrate with the solvent. In some embodiments, after the substrate is contacted with a solvent, the substrate is wiped, rinsed, dried, or any combination thereof.

In some embodiments, the solvent comprises an alcohol, a carboxylic acid, or any combination thereof. In some embodiments, the alcohol comprises a methanol, an ethanol, a propanol, an isopropyl alcohol, a butanol, an isobutyl alcohol, a pentanol, a hexanol, a cyclohexanol, a benzyl alcohol, a fatty alcohol, or any combination thereof. In some embodiments, the carboxylic acid comprises an acetic acid, a formic acid, a propionic acid, a butyric acid, a lactic acid, a citric acid, an oxalic acid, a malonic acid, a succinic acid, an adipic acid, a tartaric acid, a glutaric acid, a pimelic acid, a suberic acid, a benzoic acid, a phthalic acid, an isophthalic acid, a lauric acid, a stearic acid, or any combination thereof.

Some embodiments relate to methods for making a negative tone photoresist.

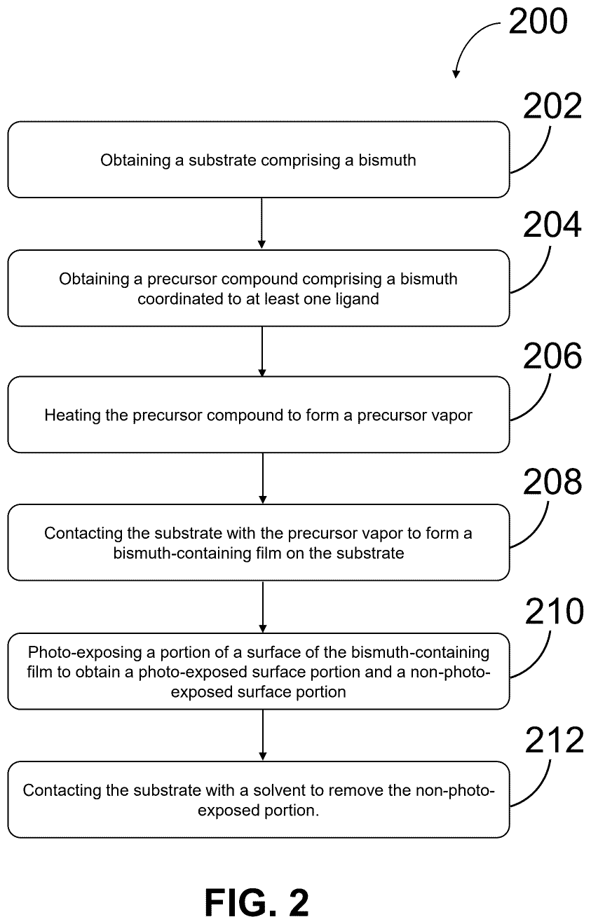

FIG. 2 is a flowchart of a method 200 for making a negative tone photoresist, according to some embodiments. As shown in FIG. 2, the method 200 for making a negative tone photoresist may comprise one or more of the following steps: obtaining a substrate comprising a bismuth 202, obtaining a precursor compound comprising a bismuth coordinated to at least one ligand 204, heating the precursor compound to form a precursor vapor 206, contacting the substrate with the precursor vapor sufficient to form a bismuth-containing film on the substrate 208, photo-exposing a portion of a surface of the bismuth-containing film to obtain a photo-exposed surface portion and a non-photo-exposed surface portion 210, and contacting the substrate with a solvent to remove the non-photo-exposed surface portion 212.

At step 202, in some embodiments, the method comprises obtaining a substrate comprising a bismuth. In some embodiments, the substrate consists of bismuth. In some embodiments, the substrate comprises a bismuth, a bismuth oxide, or any combination thereof. In some embodiments, the substrate comprises a bismuth with a bismuth oxide film on a surface of the substrate.

In some embodiments, the obtaining comprises obtaining a vessel comprising the substrate. In some embodiments, the obtaining comprises obtaining a container comprising the substrate. In some embodiments, the substrate may be obtained in a container or vessel in which the substrate will be contacted with the precursor compound.

At step 204, in some embodiments, the method comprises obtaining a precursor compound comprising a bismuth coordinated to at least one ligand. In some embodiments, the at least one ligand comprises a sulfur. In some embodiments, the precursor compound is any of the precursor compounds discussed herein. In some embodiments, the precursor compound is any of the precursor compounds discussed herein that contain a sulfur.

In some embodiments, the obtaining comprises obtaining a vessel comprising the precursor compound. In some embodiments, the obtaining comprises obtaining a container comprising the precursor compound. In some embodiments, the precursor compound may be obtained in a container or other vessel in which the precursor compound is to be heated.

At step 206, in some embodiments, the method comprises heating the precursor compound to obtain a precursor vapor. The heating may comprise heating the precursor compound sufficient to obtain the precursor vapor. In some embodiments, the heating comprises heating a container comprising the precursor compound. In some embodiments, the heating comprises heating the precursor compound in a deposition chamber in which the vapor deposition process is performed. In some embodiments, the heating comprises heating a conduit for delivering the precursor compound, the precursor vapor, or any combination thereof to, for example, a deposition chamber. In some embodiments, the heating comprises operating a vapor delivery system comprising the precursor compound. In some embodiments, the heating comprises heating to a temperature sufficient to vaporize the precursor compound to obtain the precursor vapor. In some embodiments, the heating comprises heating to a temperature below a decomposition temperature of at least one of the precursor compound, the precursor vapor, or any combination thereof. In some embodiments, the precursor compound may be present in a gas phase or other vaporizable phase, in which case the step 106 is optional and not required. For example, in some embodiments, the precursor compound comprises the precursor vapor.

At step 208, in some embodiments, the method comprises contacting the substrate with the precursor vapor to form a bismuth-containing film on the substrate. In some embodiments, the precursor vapor may be contacted with a bismuth oxide film on a surface of the substrate. In some embodiments, the contacting comprises contacting the substrate under vapor deposition conditions. The contacting may be performed in any system, apparatus, device, assembly, chamber thereof, or component thereof suitable for vapor deposition processes, including, for example and without limitation, a deposition chamber, among others.

The vapor deposition conditions may comprise conditions for vapor deposition processes. Examples of vapor deposition conditions include, without limitation, vapor deposition conditions for vapor deposition processes including at least one of a chemical vapor deposition (CVD) process, a digital or pulsed chemical vapor deposition process, a plasma-enhanced cyclical chemical vapor deposition (PECCVD) process, a flowable chemical vapor deposition (FCVD) process, an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

The vapor deposition conditions may comprise a deposition temperature. The deposition temperature may be a temperature less than the thermal decomposition temperature of the precursor vapor. The deposition temperature may be sufficiently high to reduce or avoid condensation of the precursor vapor. In some embodiments, the substrate may be heated to the deposition temperature. In some embodiments, the chamber or other vessel in which the substrate is contacted with the precursor vapor. In some embodiments, the precursor vapor may be heated to the deposition temperature.

The deposition temperature may be a temperature of 200° C. to 2500° C., or any range or subrange between 200° C. and 2500° C. In some embodiments, the deposition temperature may be a temperature of 500° C. to 700° C. For example, in some embodiments, the deposition temperature may be a temperature of 500° C. to 680° C., 500° C. to 660° C., 500° C. to 640° C., 500° C. to 620° C., 500° C. to 600° C., 500° C. to 580° C., 500° C. to 560° C., 500° C. to 540° C., 500° C. to 520° C., 520° C. to 700° C., 540° C. to 700° C., 560° C. to 700° C., 580° C. to 700° C., 600° C. to 700° C., 620° C. to 700° C., 640° C. to 700° C., 660° C. to 700° C., or 680° C. to 700° C. In other embodiments, the deposition temperature may be a temperature of greater than 200° C. to 2500° C., such as, for example and without limitation, a temperature of 400° C. to 2000, 500° C. to 2000° C., 550° C. to 2400° C., 600° C. to 2400° C., 625° C. to 2400° C., 650° C. to 2400° C., 675° C. to 2400° C., 700° C. to 2400° C., 725° C. to 2400° C., 750° C. to 2400° C., 775° C. to 2400° C., 800° C. to 2400° C., 825° C. to 2400° C., 850° C. to 2400° C., 875° C. to 2400° C., 900° C. to 2400° C., 925° C. to 2400° C., 950° C. to 2400° C., 975° C. to 2400° C., 1000° C. to 2400° C., 1025° C. to 2400° C., 1050° C. to 2400° C., 1075° C. to 2400° C., 1100° C. to 2400° C., 1200° C. to 2400° C., 1300° C. to 2400° C., 1400° C. to 2400° C., 1500° C. to 2400° C., 1600° C. to 2400° C., 1700° C. to 2400° C., 1800° C. to 2400° C., 1900° C. to 2400° C., 2000° C. to 2400° C., 2100° C. to 2400° C., 2200° C. to 2400° C., 2300° C. to 2400° C., 500° C. to 2000° C., 500° C. to 1900° C., 500° C. to 1800° C., 500° C. to 1700° C., 500° C. to 1600° C., 500° C. to 1500° C., 500° C. to 1400° C., 500° C. to 1300° C., 500° C. to 1200° C., 500° C. to 1100° C., 500° C. to 1000° C., 500° C. to 1000° C., 500° C. to 900° C., or 500° C. to 800° C.

The vapor deposition conditions may comprise a deposition pressure. In some embodiments, the deposition pressure may comprise a vapor pressure of the precursor vapor. In some embodiments, the deposition pressure may comprise a chamber pressure.

The deposition pressure may be a pressure of 0.001 Torr to 100 Torr, or any range or subrange between 0.001 Torr and 100 Torr. For example, in some embodiments, the deposition pressure may be a pressure of 1 Torr to 30 Torr, 1 Torr to 25 Torr, 1 Torr to 20 Torr, 1 Torr to 15 Torr, 1 Torr to 10 Torr, 5 Torr to 50 Torr, 5 Torr to 40 Torr, 5 Torr to 30 Torr, 5 Torr to 20 Torr, or 5 Torr to 15 Torr. In other embodiments, the deposition pressure may be a pressure of 1 Torr to 100 Torr, 5 Torr to 100 Torr, 10 Torr to 100 Torr, 15 Torr to 100 Torr, 20 Torr to 100 Torr, 25 Torr to 100 Torr, 30 Torr to 100 Torr, 35 Torr to 100 Torr, 40 Torr to 100 Torr, 45 Torr to 100 Torr, 50 Torr to 100 Torr, 55 Torr to 100 Torr, 60 Torr to 100 Torr, 65 Torr to 100 Torr, 70 Torr to 100 Torr, 75 Torr to 100 Torr, 80 Torr to 100 Torr, 85 Torr to 100 Torr, 90 Torr to 100 Torr, 95 Torr to 100 Torr, 1 Torr to 95 Torr, 1 Torr to 90 Torr, 1 Torr to 85 Torr, 1 Torr to 80 Torr, 1 Torr to 75 Torr, or 1 Torr to 70 Torr. In other further embodiments, the deposition pressure may be a pressure of 1 mTorr to 100 mTorr, 1 mTorr to 90 mTorr, 1 mTorr to 80 mTorr, 1 mTorr to 70 mTorr, 1 mTorr to 60 mTorr, 1 mTorr to 50 mTorr, 1 mTorr to 40 mTorr, 1 mTorr to 30 mTorr, 1 mTorr to 20 mTorr, 1 mTorr to 10 mTorr, 100 mTorr to 300 mTorr, 150 mTorr to 300 mTorr, 200 mTorr to 300 mTorr, or 150 mTorr to 250 mTorr, or 150 mTorr to 225 mTorr.

At step 210, in some embodiments, the method comprises photo-exposing a portion of a surface of the bismuth-containing film to obtain a photo-exposed surface portion and a non-photo-exposed surface portion. In some embodiments, the photo-exposing is conducted using extreme ultraviolet light. In some embodiments, the photo-exposed surface portion comprises a bismuth sulfide.

At step 212, in some embodiments, the method comprises contacting the substrate with a solvent to remove the non-photo-exposed surface portion. In some embodiments, the contacting involves washing the substrate with the solvent. In some embodiments, the contacting involves wiping the substrate with the solvent. In some embodiments, the contacting involves spraying the substrate with the solvent. In some embodiments, after the substrate is contacted with a solvent, the substrate is wiped, rinsed, dried, or any combination thereof.

In some embodiments, the solvent comprises an alcohol, a carboxylic acid, or any combination thereof. In some embodiments, the alcohol comprises a methanol, an ethanol, a propanol, an isopropyl alcohol, a butanol, an isobutyl alcohol, a pentanol, a hexanol, a cyclohexanol, a benzyl alcohol, a fatty alcohol, or any combination thereof. In some embodiments, the carboxylic acid comprises an acetic acid, a formic acid, a propionic acid, a butyric acid, a lactic acid, a citric acid, an oxalic acid, a malonic acid, a succinic acid, an adipic acid, a tartaric acid, a glutaric acid, a pimelic acid, a suberic acid, a benzoic acid, a phthalic acid, an isophthalic acid, a lauric acid, a stearic acid, or any combination thereof.

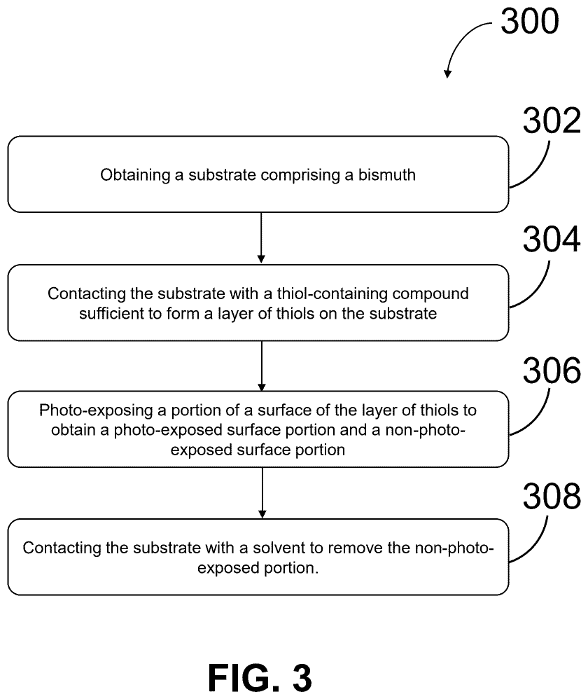

FIG. 3 is a flowchart of a method 300 for making a negative tone photoresist, according to some embodiments. As shown in FIG. 3, the method 300 for making a negative tone photoresist may comprise one or more of the following steps: obtaining a substrate comprising a bismuth 302, contacting the substrate with a thiol-containing compound sufficient to form a layer of thiols on the substrate 304, photo-exposing a portion of a surface of the layer of thiols to obtain a photo-exposed surface portion and a non-photo-exposed surface portion 306, and contacting the substrate with a solvent to remove the non-photo-exposed surface portion 308.

At step 302, in some embodiments, the method comprises obtaining a substrate comprising a bismuth. In some embodiments, the substrate consists of bismuth. In some embodiments, the substrate comprises a bismuth, a bismuth oxide, or any combination thereof. In some embodiments, the substrate comprises a bismuth with a bismuth oxide film on a surface of the substrate.

In some embodiments, the obtaining comprises obtaining a vessel comprising the substrate. In some embodiments, the obtaining comprises obtaining a container comprising the substrate. In some embodiments, the substrate may be obtained in a container or vessel in which the substrate will be contacted with the precursor compound.

At step 304, in some embodiments, the method comprises contacting the substrate with a thiol-containing compound sufficient to form a layer of thiols on the substrate. In some embodiments, the thiol-containing compound contacts a bismuth oxide film on a surface of the substrate. In some embodiments, the thiol-containing compound comprises an alkylthiol, a thiourea, or a combination thereof.

At step 306, in some embodiments, the method comprises photo-exposing a portion of a surface of the layer of thiols to obtain a photo-exposed surface portion and a non-photo-exposed surface portion. In some embodiments, the photo-exposing is conducted using extreme ultraviolet light. In some embodiments, the photo-exposed surface portion comprises a bismuth sulfide.

At step 312, in some embodiments, the method comprises contacting the substrate with a solvent to remove the non-photo-exposed surface portion. In some embodiments, the contacting involves washing the substrate with the solvent. In some embodiments, the contacting involves wiping the substrate with the solvent. In some embodiments, the contacting involves spraying the substrate with the solvent. In some embodiments, after the substrate is contacted with a solvent, the substrate is wiped, rinsed, dried, or any combination thereof.

In some embodiments, the solvent comprises an alcohol, a carboxylic acid, or any combination thereof. In some embodiments, the alcohol comprises a methanol, an ethanol, a propanol, an isopropyl alcohol, a butanol, an isobutyl alcohol, a pentanol, a hexanol, a cyclohexanol, a benzyl alcohol, a fatty alcohol, or any combination thereof. In some embodiments, the carboxylic acid comprises an acetic acid, a formic acid, a propionic acid, a butyric acid, a lactic acid, a citric acid, an oxalic acid, a malonic acid, a succinic acid, an adipic acid, a tartaric acid, a glutaric acid, a pimelic acid, a suberic acid, a benzoic acid, a phthalic acid, an isophthalic acid, a lauric acid, a stearic acid, or any combination thereof.

In some embodiments, before contacting the substrate with a solvent, the substrate is contacted with oxygen. In some embodiments, after the substrate is contacted with oxygen, the non-photo-exposed portion comprises a bismuth oxide and the photo-exposed portion comprises a bismuth sulfide.

Any one or more of the embodiments disclosed herein shall be understood to be combinable without departing from the scope or spirit of the disclosure.

### EXAMPLE 1: POSITIVE TONE PHOTORESIST

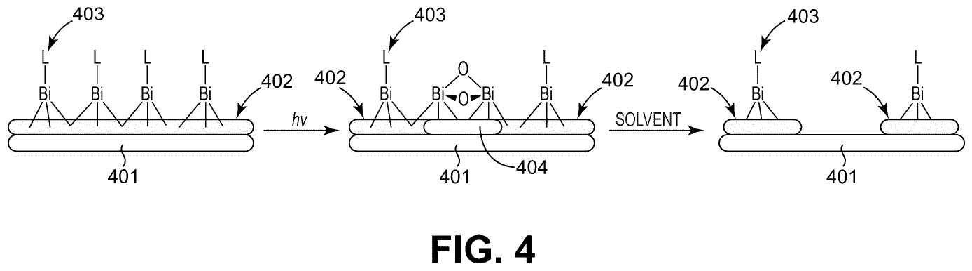

FIG. 4 illustrates the method of making a positive tone photoresist of Example 1. A substrate 401 comprising a bismuth is obtained. The substrate 401 comprises a bismuth sulfide film 402 on the surface. A precursor compound comprising a bismuth coordinated to at least one ligand is obtained. The at least one ligand comprises an oxygen. The precursor compound is heated to form a precursor vapor and then contacted with the bismuth sulfide film 402 to form a bismuth-containing film 403 on the bismuth sulfide film 402. A portion of the bismuth-containing film 403 is photo-exposed to produce a photo-exposed portion 404. The photo-exposed portion 404 comprises a bismuth oxide. The substrate 401 is contacted with a solvent and the photo-exposed portion 404 is removed creating a positive tone photoresist.

### EXAMPLE 2: NEGATIVE TONE PHOTORESIST

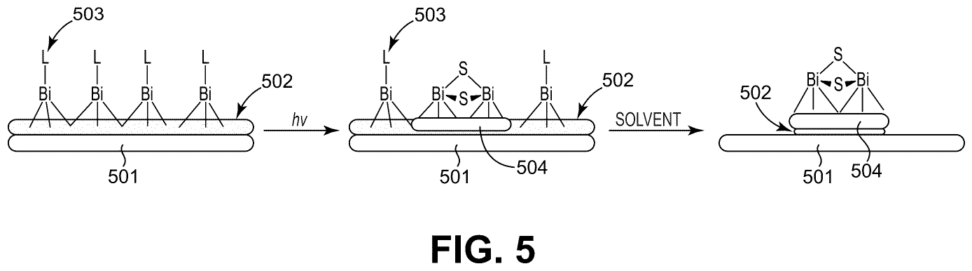

FIG. 5 illustrates the method of making a negative tone photoresist of Example 2. A substrate 501 comprising a bismuth is obtained. The substrate 501 comprises a bismuth oxide film 502 on the surface. A precursor compound comprising a bismuth coordinated to at least one ligand is obtained. The at least one ligand comprises a sulfur. The precursor compound is heated to form a precursor vapor and then contacted with the bismuth oxide film 502 to form a bismuth-containing film 503 on the bismuth oxide film 502. A portion of the bismuth-containing film 503 is photo-exposed to produce a photo-exposed portion 504. The photo-exposed portion 504 comprises a bismuth sulfide. The substrate 501 is contacted with a solvent, removing the non-photo-exposed portion, i.e. bismuth oxide film 502 and bismuth-containing film 503, leaving the photo-exposed portion 504 and creating a negative tone photoresist.

### EXAMPLE 3: NEGATIVE TONE PHOTORESIST

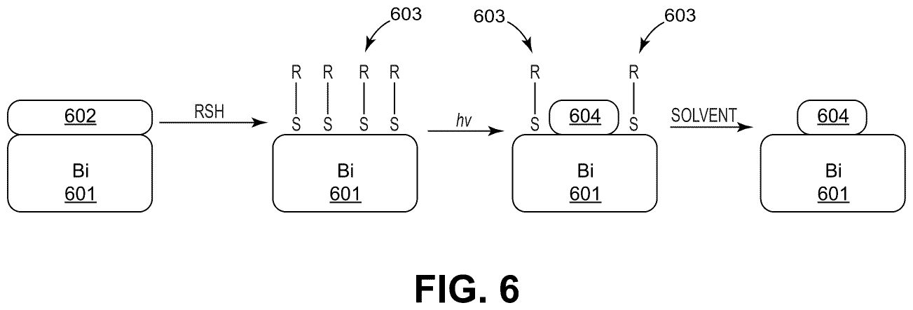

FIG. 6 illustrates the method of making a negative tone photoresist of Example 3. A substrate 601 comprising a bismuth is obtained. The substrate 601 comprises a bismuth oxide film 602 on the surface. The substrate 601 is contacted with a thiol containing compound to form a layer of thiols 603 on the surface of the substrate 601. A portion of the layer of thiols 603 is photo-exposed to produce a photo-exposed portion 604. The photo-exposed portion 604 comprises a bismuth sulfide. The substrate 601 is contacted with a solvent, removing the non-photo-exposed portion, i.e. the remaining layer of thiols 603, leaving the photo-exposed portion 604 and creating a negative tone photoresist.

### ASPECTS

Various Aspects are described below. It is to be understood that any one or more of the features recited in the following Aspect(s) can be combined with any one or more other Aspect(s).

Aspect 1. A method comprising:
obtaining a substrate comprising a bismuth,
obtaining a precursor compound comprising a bismuth coordinated to at least one ligand,
   wherein the at least one ligand comprises an oxygen;
heating the precursor compound to form a precursor vapor;
contacting the substrate with the precursor vapor sufficient to form a bismuth-containing film on the substrate;
photo-exposing a portion of a surface of the bismuth-containing film to obtain a photo-exposed surface portion and a non-photo-exposed surface portion; and
contacting the substrate with a solvent to remove the photo-exposed surface portion.

Aspect 2. The method according to Aspect 1, wherein the substrate comprises a bismuth sulfide film on a surface of the substrate and wherein the precursor compound contacts the bismuth sulfide film.

Aspect 3. The method according to Aspect 2, wherein the bismuth sulfide film is obtained by:
contacting the substrate with a thiol-containing compound sufficient to form a layer of thiols on the substrate; and
photo-exposing the layer of thiols to form the bismuth sulfide film.

Aspect 4. The method according to Aspect 3, wherein the thiol-containing compound comprises an alkylthiol, a thiolurea, or a combination thereof.

Aspect 5. The method according to any one of Aspects 1-4, wherein the solvent comprises an alcohol, a carboxylic acid, or any combination thereof.

Aspect 6. The method according to any one of Aspects 1-5, wherein the photo-exposing is conducted using extreme ultraviolet light.

Aspect 7. The method according to any one of Aspects 1-6, wherein the photo-exposed surface portion comprises a bismuth oxide.

Aspect 8. A method comprising:
obtaining a substrate comprising a bismuth;
obtaining a precursor compound comprising a bismuth coordinated to at least one ligand,
   wherein the at least one ligand comprises a sulfur;
heating the precursor compound to form a precursor vapor;
contacting the substrate with the precursor vapor sufficient to form a bismuth-containing film on the substrate;
photo-exposing a portion of a surface of the bismuth-containing film to obtain a photo-exposed surface portion and a non-photo-exposed surface portion; and
contacting the substrate with a solvent to remove the non-photo-exposed surface portion.

Aspect 9. The method according to Aspect 8, wherein the substrate comprises a bismuth oxide film on a surface of the substrate and wherein the precursor contacts the bismuth oxide film.

Aspect 10. The method according to any one of Aspects 8-9, wherein the solvent comprises an alcohol, a carboxylic acid, or any combination thereof.

Aspect 11. The method according to any one of Aspects 8-10, wherein the photo-exposing is conducted using extreme ultraviolet light.

Aspect 12. The method according to any one of Aspects 8-11, wherein the photo-exposed surface portion comprises a bismuth sulfide.

Aspect 13. A method comprising:
obtaining a substrate comprising a bismuth;
contacting the substrate with a thiol-containing compound sufficient to form a layer of thiols on the substrate;
photo-exposing a portion of a surface of the layer of thiols to obtain a photo-exposed surface portion and a non-photo-exposed surface portion; and
contacting the substrate with a solvent to remove the non-photo-exposed surface portion.

Aspect 14. The method according to Aspect 13, wherein the substrate comprises a bismuth oxide film on a surface of the substrate and wherein the thiol-containing compound contacts the bismuth oxide film.

Aspect 15. The method according to any one of Aspects 13-14, wherein the photo-exposed surface portion comprises a bismuth sulfide.

Aspect 16. The method according to any one of Aspects 13-15, wherein before contacting the substrate with a solvent, the substrate is contacted with oxygen.

Aspect 17. The method according to Aspect 16, wherein the non-photo-exposed portion comprises a bismuth oxide and the photo-exposed portion comprises a bismuth sulfide.

Aspect 18. The method according to any one of Aspects 13-17, wherein the solvent comprises an alcohol, a carboxylic acid, or any combination thereof.

Aspect 19. The method according to any one of Aspects 13-18, wherein the thiol-containing compound comprises an alkylthiol, a thiourea, or any combination thereof.

Aspect 20. The method of according to any one of Aspects 13-19, wherein the photo-exposing is conducted using extreme ultraviolet light.

What is claimed is:

1. A method comprising:
obtaining a substrate comprising a bismuth,
obtaining a precursor compound comprising a bismuth coordinated to at least one ligand,
wherein the at least one ligand comprises an oxygen;
heating the precursor compound to form a precursor vapor;
contacting the substrate with the precursor vapor sufficient to form a bismuth-containing film on the substrate;
photo-exposing a portion of a surface of the bismuth-containing film to obtain a photo-exposed surface portion and a non-photo-exposed surface portion; and
contacting the substrate with a solvent to remove the photo-exposed surface portion.

2. The method of claim 1, wherein the substrate comprises a bismuth sulfide film on a surface of the substrate and wherein the precursor compound contacts the bismuth sulfide film.

3. The method of claim 2, wherein the bismuth sulfide film is obtained by:
contacting the substrate with a thiol-containing compound sufficient to form a layer of thiols on the substrate; and
photo-exposing the layer of thiols to form the bismuth sulfide film.

4. The method of claim 3, wherein the thiol-containing compound comprises an alkylthiol, a thiolurea, or a combination thereof.

5. The method of claim 1, wherein the solvent comprises an alcohol, a carboxylic acid, or any combination thereof.

6. The method of claim 1, wherein the photo-exposing is conducted using extreme ultraviolet light.

7. The method of claim 1, wherein the photo-exposed surface portion comprises a bismuth oxide.

8. A method comprising:
obtaining a substrate comprising a bismuth;
obtaining a precursor compound comprising a bismuth coordinated to at least one ligand,
wherein the at least one ligand comprises a sulfur;
heating the precursor compound to form a precursor vapor;
contacting the substrate with the precursor vapor sufficient to form a bismuth-containing film on the substrate;
photo-exposing a portion of a surface of the bismuth-containing film to obtain a photo-exposed surface portion and a non-photo-exposed surface portion; and
contacting the substrate with a solvent to remove the non-photo-exposed surface portion.

9. The method of claim 8, wherein the substrate comprises a bismuth oxide film on a surface of the substrate and wherein the precursor contacts the bismuth oxide film.

10. The method of claim 8, wherein the solvent comprises an alcohol, a carboxylic acid, or any combination thereof.

11. The method of claim 8, wherein the photo-exposing is conducted using extreme ultraviolet light.

12. The method of claim 8, wherein the photo-exposed surface portion comprises a bismuth sulfide.

13. A method comprising:
obtaining a substrate comprising a bismuth;
contacting the substrate with a thiol-containing compound sufficient to form a layer of thiols on the substrate;
photo-exposing a portion of a surface of the layer of thiols to obtain a photo-exposed surface portion and a non-photo-exposed surface portion; and
contacting the substrate with a solvent to remove the non-photo-exposed surface portion.

14. The method of claim 13, wherein the substrate comprises a bismuth oxide film on a surface of the substrate and wherein the thiol-containing compound contacts the bismuth oxide film.

15. The method of claim 13, wherein the photo-exposed surface portion comprises a bismuth sulfide.

16. The method of claim 13, wherein before contacting the substrate with a solvent, the substrate is contacted with oxygen.

17. The method of claim 16, wherein the non-photo-exposed portion comprises a bismuth oxide and the photo-exposed portion comprises a bismuth sulfide.

18. The method of claim 13, wherein the solvent comprises an alcohol, a carboxylic acid, or any combination thereof.

19. The method of claim 13, wherein the thiol-containing compound comprises an alkylthiol, a thiourea, or any combination thereof.

20. The method of claim 13, wherein the photo-exposing is conducted using extreme ultraviolet light.
